(19) United States
(12) Patent Application Publication
(10) Pub. No.: US 2022/0102331 A1
(43) Pub. Date: Mar. 31, 2022

(54) DISPLAY DEVICE

(71) Applicant: Samsung Display Co., LTD., Yongin-si, Gyeonggi-do (KR)

(72) Inventors: Young Rag DO, Seoul (KR); Hoo Keun PARK, Cheongju-si, Chungcheongbuk-do (KR)

(73) Assignee: Samsung Display Co., LTD., Yongin-si, Gyeonggi-do (KR)

(21) Appl. No.: 17/423,321

(22) PCT Filed: Nov. 25, 2019
(86) PCT No.: PCT/KR2019/016252

§ 371 Date: Jul. 15, 2021

(30) Foreign Application Priority Data
Jan. 15, 2019 (KR) 10-2019-0005433

(51) Int. Cl. H01L 25/16; H01L 27/12

(52) U.S. Cl. CPC H01L 25/167; H01L 33/24; H01L 27/1225; H01L 27/124

(57) ABSTRACT

A display device includes a light-emitting element; a first transistor that transmits a driving current to the light-emitting element; and a second transistor that transmits a data signal to the first transistor. The first transistor includes a first active layer, the second transistor includes a second active layer including an oxide semiconductor, and the light-emitting element includes a first conductivity type semiconductor having a first polarity, a second conductivity-type semiconductor having a second polarity different from the first polarity, and an active layer arranged between the first conductivity type semiconductor and the second conductivity-type semiconductor.

### CROSS-REFERENCE TO RELATED APPLICATION(S)

This application is a national entry of International Application No. PCT/KR2019/016252, filed on Nov. 25, 2019, which claims under 35 U.S.C. §§119(a) and 365(b) priority to and benefits of Korean Patent Application No. 10-2019-0005433, filed on Jan. 15, 2019 in the Korean Intellectual Property Office (KIPO), the entire contents of which are incorporated herein by reference.

### BACKGROUND

### 1. Technical Field

The disclosure relates to a display device, and more specifically, to a display device including a light-emitting element having a micrometer or nanometer unit size and an oxide thin film transistor.

### 2. Description of Related Art

With the development of multimedia, display devices are becoming more important. In response to the development, various types of display devices, such as organic light emitting diode (OLED) display devices, liquid crystal display (LCD) devices, and the like, are being used.

A device for displaying an image of a display device includes a display panel such as an OLED panel or an LCD panel. Among the above panels, a light emitting display panel may include a light emitting element. For example, an LED includes an OLED using an organic material as a fluorescent material, and an inorganic LED using an inorganic material as a fluorescent material.

The inorganic LED using an inorganic semiconductor as a fluorescent material has durability in a high temperature environment and has an advantage of high efficiency of blue light as compared with the OLED. Further, even in a manufacturing process which has been pointed out as a limitation of the conventional inorganic LED element, a transfer method using dielectrophoresis (DEP) has been developed. Therefore, research is being carried out on inorganic LEDs having excellent durability and excellent efficiency as compared with OLEDs.

### SUMMARY

The disclosure is directed to providing a display device including an oxide thin film transistor as a circuit element layer for driving a light-emitting element having a fine size.

It should be noted that objects of the disclosure are not limited to the above-described objects, and other objects of the disclosure will be apparent to those skilled in the art from the following descriptions.

According to an embodiment, a display device may include a light-emitting element, a first transistor that transmits a driving current to the light-emitting element, a second transistor that transmits a data signal to the first transistor. The first transistor may include a first active layer, the second transistor may include a second active layer including an oxide semiconductor, and the light-emitting element may include a first conductivity type semiconductor having a first polarity, a second conductivity type semiconductor having a second polarity different from the first polarity, and an active layer disposed between the first conductivity type semiconductor and the second conductivity type semiconductor.

The first active layer of the first transistor may include an oxide semiconductor.

The oxide semiconductor of each of the first active layer and the second active layer may include indium-gallium-tin oxide (IGTO) or indium-gallium-zinc-tin oxide (IGZTO).

A length of the light-emitting element may be in a range of about 4 μm to about 7 μm, and an aspect ratio of the light-emitting element may be in a range of about 1.2 to about 100.

The first transistor may include a first gate electrode disposed below the first active layer.

The first active layer may include a first conductorized region, a second conductorized region, and a channel region disposed between the first conductorized region and the second conductorized region.

The first transistor may further include a third gate electrode disposed on the first active layer, a first source electrode electrically connected to the first conductorized region through a first contact hole passing through an interlayer insulating film disposed on the third gate electrode, and a first drain electrode electrically connected to the second conductorized region through a second contact hole passing through the interlayer insulating film.

The first active layer may include polycrystalline silicon.

The first transistor may further include a light blocking layer disposed below the first active layer.

The second transistor may include a second gate electrode disposed below the second active layer, a second source electrode electrically connected to a side of the second active layer, and a second drain electrode electrically connected to another side of the second active layer.

The display device may further comprise a data line that transmits the data signal. The data line may further include a conductive pattern spaced apart from the second source electrode of the second transistor and electrically connected to the data line and the second source electrode.

According to another embodiment, a display device may include a first gate electrode disposed on a substrate, a first gate insulating film disposed on the first gate electrode, a first active layer disposed on the first gate insulating film, at least partially overlapping the first gate electrode, and including an oxide semiconductor, a first interlayer insulating film disposed on the first active layer, a second gate electrode disposed on the first interlayer insulating film, a second interlayer insulating film disposed on the second gate electrode, a second active layer disposed on the second interlayer insulating film, at least partially overlapping the second gate electrode, and including an oxide semiconductor, and a first conductive layer including a first signal line disposed on the second interlayer insulating film and a source electrode formed on one side of the second active layer, wherein the first conductive layer further includes a conductive pattern at least partially overlapping a side of the source electrode and the first signal line.

The display device may further include a drain electrode disposed on the first gate insulating film and electrically contacting one side of the first active layer, a via layer disposed on the first conductive layer, and at least one light-emitting element disposed on the via layer, wherein the drain electrode is electrically connected to an end of the at least one light-emitting element.

The light-emitting element may include a first conductivity type semiconductor having a first polarity, a second conductivity type semiconductor having a second polarity different from the first polarity, and an active layer disposed between the first conductivity type semiconductor and the second conductivity type semiconductor.

According to another embodiment, a display device may include a base layer, a first electrode and a second electrode disposed on the base layer and spaced apart from each other in a first direction, at least one light-emitting element electrically connected to at least one of the first electrode and the second electrode and extending in the first direction, a driving transistor that transmits a driving current to the at least one light-emitting element. The driving transistor may include an active layer having an oxide semiconductor, and the at least one light-emitting element may include a first conductivity type semiconductor having a first polarity, a second conductivity type semiconductor having a second polarity different from the first polarity, and an active layer disposed between the first conductivity type semiconductor and the second conductivity type semiconductor.

The driving transistor may have a gate electrode disposed below the active layer.

Each of the first electrode and the second electrode may extend in a second direction different from the first direction.

The display device may further include a first contact electrode electrically contacting the first electrode and an end portion of the at least one light-emitting element; and a second contact electrode electrically contacting the second electrode and another end portion of the at least one light-emitting element.

A length of the at least one light-emitting element in the first direction may be in a range of about 4 μm to about 7 μm, and an aspect ratio of the at least one light-emitting element may be in a range of about 1.2 to about 100.

The first conductivity type semiconductor, the active layer, and the second conductivity type semiconductor may be disposed in a direction parallel to an upper surface of the base layer.

The details of other embodiments are included in the detailed description and the accompanying drawings.

In accordance with the disclosure, a display device includes a light-emitting element having a micrometer or nanometer unit size.

In accordance with the disclosure, the display device includes a driving transistor including an oxide semiconductor and can drive the light-emitting element having the fine size.

The effects according to the embodiments are not limited by the contents exemplified above, and more various effects are included in this disclosure.

### BRIEF DESCRIPTION OF THE DRAWINGS

An additional appreciation according to the embodiments of the disclosure will become more apparent by describing in detail the embodiments thereof with reference to the accompanying drawings, wherein:

FIG. 1 is a perspective view schematically illustrating a display device according to one embodiment.

FIG. 2 is a schematic block diagram schematically illustrating the display device according to one embodiment.

FIG. 3 is a schematic plan view schematically illustrating a display panel of FIG. 1.

FIG. 4 is a circuit diagram schematically illustrating one pixel of FIG. 2.

FIG. 5 is a schematic enlarged schematic diagram of portion A of FIG. 3.

FIG. 6 is a cross-sectional view schematically illustrating a circuit element layer taken along line I-I′ of FIG. 5.

FIG. 7 is a partial plan view schematically illustrating a circuit element layer according to one embodiment.

FIG. 8 is a schematic cross-sectional view taken along line IIa-IIa′ of FIG. 7.

FIG. 9 is a cross-sectional view schematically illustrating the display element layer taken along lines I-I′ and II-II′ of FIG. 5.

FIGS. 10 to 12 are cross-sectional views schematically illustrating a circuit element layer according to another embodiment.

FIG. 13 is a schematic diagram schematically illustrating a light-emitting element according to one embodiment.

FIG. 14 is a schematic diagram schematically illustrating a light-emitting element according to another embodiment.

### DETAILED DESCRIPTION OF THE EMBODIMENTS

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be thorough and complete, and will convey the scope of the disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

The phrase “at least one of” is intended to include the meaning of “at least one selected from the group of” for the purpose of its meaning and interpretation. For example, “at least one of A and B” may be understood to mean “A, B, or A and B.”

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments of the disclosure will be described with reference to the accompanying drawings.

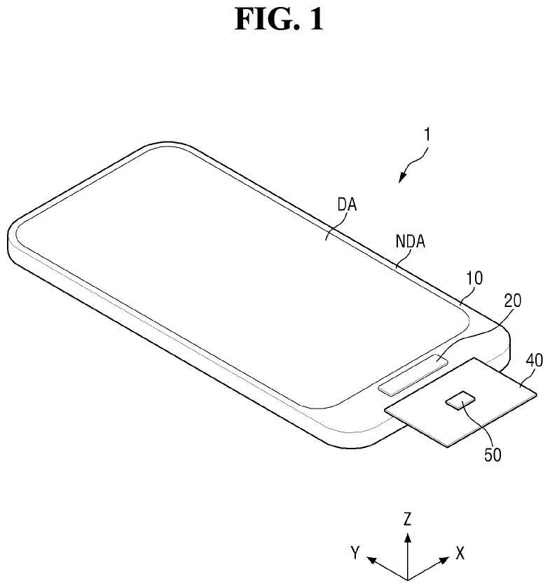

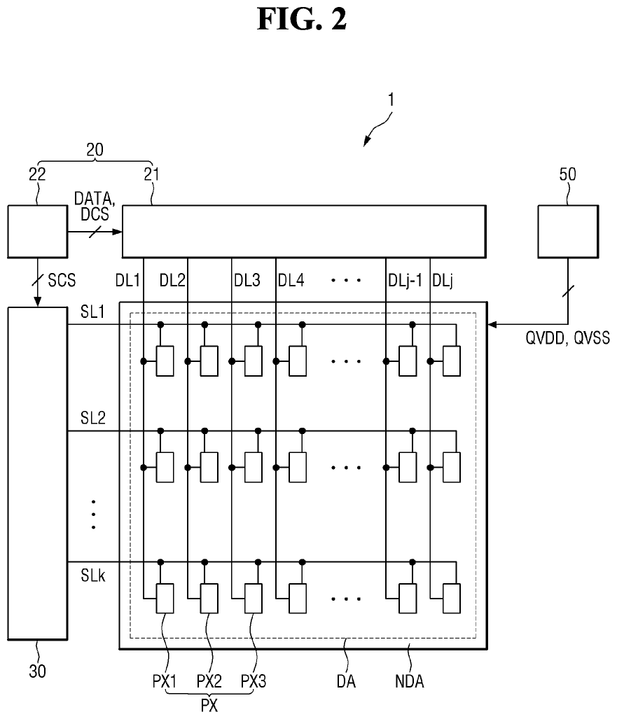

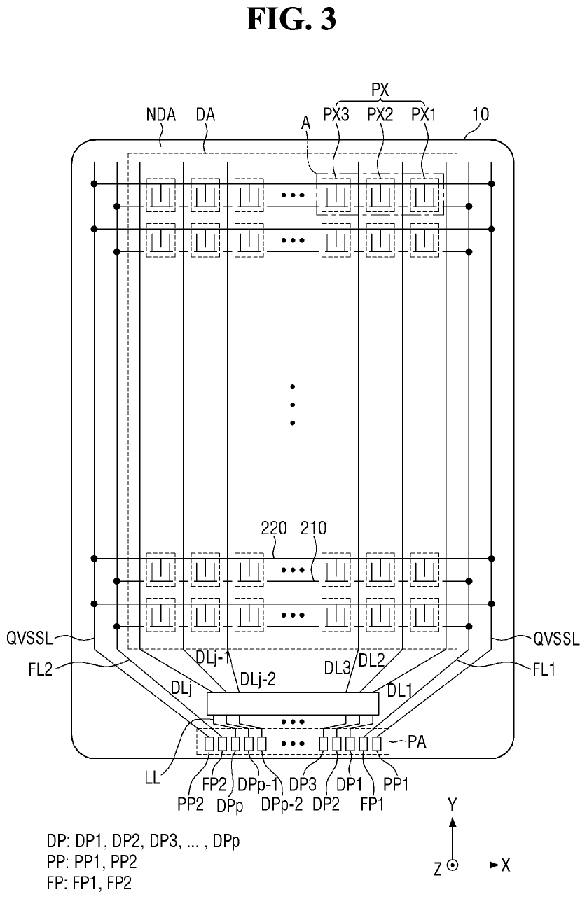

FIG. 1 is a schematic perspective view illustrating a display device according to an embodiment. FIG. 2 is a schematic block diagram illustrating the display device according to an embodiment. FIG. 3 is a schematic plan view illustrating a display panel of FIG. 1.

Referring to FIGS. 1 to 3, a display device 1 according to an embodiment includes a display panel 10, an integrated driving circuit 20, a scan driver 30, a circuit board 40, and a power supply circuit 50. The integrated driving circuit 20 may include a data driver 21 and a timing controller 22.

In this specification, the terms “upper portion,” “top,” and “upper surface” indicate a Z-axis direction, and the terms “lower portion,” “bottom,” and “lower surface” indicate a direction opposite to the Z-axis direction. The terms “left,” “right,” “upper,” and “lower” refer to directions when the display panel 10 is viewed from above (or in a plan view). For example, the term “left” refers to a direction opposite to an X-axis direction, the term “right” refers to the X-axis direction, the term “upper” refers to a Y-axis direction, and the term “lower” refers to a direction opposite the Y-axis direction.

The display panel 10 may be formed in a rectangular shape in a plan view. For example, as shown in FIG. 1, the display panel 10 may have a planar form of a rectangular shape having a short side in a first direction (the X-axis direction) and a long side in a second direction (the Y-axis direction). A corner at which the short side in the first direction (the X-axis direction) and the long side in the second direction (the Y-axis direction) meet each other may be formed at a right angle or formed to be rounded to have a predetermined curvature. The planar form of the display panel 10 is not limited to a rectangular shape and may be formed in a polygonal shape, a circular shape, or an elliptical shape which is different from the rectangular shape. Although FIG. 1 illustrates that the display panel 10 is flat, the disclosure is not limited thereto. At least one side of the display panel 10 may be bent at a predetermined curvature.

The display panel 10 may be divided into a display area DA and a non-display area NDA disposed in a peripheral area of (or adjacent to) the display area DA. The display area DA may be an area in which pixels PX are formed to display an image. The display panel 10 may include data lines DL1 to DLm (where m is an integer equal to or greater than two), scan lines SL1 to SLn (where n is an integer equal to or greater than two) intersecting the data lines DL1 to DLm, first voltage lines QVDDL which supply a first voltage, second voltage lines QVSSL which supply a second voltage, and pixels PX electrically connected to the data lines DL1 to DLm and the scan lines SL1 to SLn.

Each pixel PX may include one or more light-emitting elements 300, which emit light in a specific wavelength range, to display a color. The light emitted from the light-emitting element 300 may be displayed to the outside through the display area DA of the display panel 10.

Each pixel PX may include a first sub-pixel PX1, a second sub-pixel PX2, and a third sub-pixel PX3. The first sub-pixel PX1 may emit light of a first color, the second sub-pixel PX2 may emit light of a second color, and the third sub-pixel PX3 may emit light of a third color. The first color may be red, the second color may be green, and the third color may be blue, but the disclosure is not limited thereto. In some cases, sub-pixels PXn may emit pieces of light having a same color. Although each pixel PX has been illustrated as including three sub-pixels in FIG. 2, the disclosure is not limited thereto, and each pixel PX may include four or more sub-pixels.

The integrated driving circuit 20 outputs signals and voltages for driving the display panel 10. To this end, the integrated driving circuit 20 may include a data driver 21 and a timing controller 22.

The data driver 21 receives digital video data DATA and a source control signal DCS from the timing controller 22. In response to the source control signal DCS, the data driver 21 converts the digital video data DATA into analog data voltages and supplies the analog data voltages to the data lines DL1 to DLm of the display panel 10.

The timing controller 22 may receive the digital video data DATA and timing signals from a host system. The timing signals may include a vertical sync signal, a horizontal sync signal, a data enable signal, and a dot clock. The host system may be an application processor of a smartphone or a tablet personal computer (PC), or a system on chip of a monitor or a television (TV).

The timing controller 22 generates control signals to control operation timings of the data driver 21 and the scan driver 30. The control signals may include the source control signal DCS for controlling an operation timing of the data driver 21 and a scan control signal SCS for controlling an operation timing of the scan driver 30.

The integrated driving circuit 20 may be disposed in the non-display area NDA provided on a side of the display panel 10. The integrated driving circuit 20 may be formed as an integrated circuit (IC) and disposed on the display panel 10 by a chip on glass (COG) method, a chip on plastic (COP) method, or an ultrasonic bonding method. However, the disclosure is not limited thereto. For example, the integrated driving circuit 20 may be mounted on the circuit board 40 instead of the display panel 10.

Although FIG. 2 illustrates that the integrated driving circuit 20 includes the data driver 21 and the timing controller 22, the disclosure is not limited thereto. The data driver 21 and the timing controller 22 may not be formed as a single integrated circuit (IC) but may be formed as separate ICs. The data driver 21 may be mounted on the display panel 10 by a COG method, a COP method, or an ultrasonic bonding method, and the timing controller 22 may be mounted on the circuit board 40.

The scan driver 30 receives the scan control signal SCS from the timing controller 22. In response to the scan control signal SCS, the scan driver 30 generates scan signals and supplies the scan signals to the scan lines SL1 to SLn of the display panel 10. The scan driver 30 may include transistors and may be formed in the non-display area NDA of the display panel 10. As another example, the scan driver 30 may be formed as an IC, and the scan driver 30 may be mounted on a gate flexible film attached to another side of the display panel 10.

The circuit board 40 may be attached on pads provided at an edge of a side of the display panel 10 by using an anisotropic conductive film. Consequently, lead lines of the circuit board 40 may be electrically connected to the pads. The circuit board 40 may be a flexible film such as a flexible printed circuit board, a printed circuit board, or a chip on film (COF). The circuit board 40 may be bent downward from the display panel 10. A side of the circuit board 40 may be attached to an edge of a side of the display panel 10, and another side thereof may be disposed below the display panel 10 and electrically connected to a system board on which the host system is mounted.

The power supply circuit 50 may generate voltages required to drive the display panel 10 from main power applied from the system board and supply the voltages to the display panel 10. For example, the power supply circuit 50 may generate a first voltage QVDD and a second voltage QVSS for driving the light-emitting elements 300 of the display panel 10 from the main power and supply the first voltage QVDD and the second voltage QVSS to the first voltage line QVDDL and the second voltage line QVSSL of the display panel 10. The power supply circuit 50 may generate and supply driving voltages for driving the integrated driving circuit 20 and the scan driver 30 from the main power.

Although FIG. 1 illustrates that the power supply circuit 50 is formed as the IC and mounted on the circuit board 40, the embodiment of the disclosure is not limited thereto. For example, the power supply circuit 50 may be integrated into (or may be integral with) the integrated driving circuit 20.

FIG. 3 illustrates a schematic plan view of the display panel 10 of FIG. 1 in a relatively detailed manner. For convenience of description, FIG. 3 illustrates only data pads DP1 to DPp (where p is an integer equal to or greater than two), floating pads FP1 and FP2, power pads PP1 and PP2, floating lines FL1 and FL2, the second voltage line QVSSL, the data lines DL1 to DLm, first electrode lines 210, and second electrode lines 220.

Referring to FIG. 3, the pixels PX may be disposed in the display area DA of the display panel 10, and the electrode lines 210 and 220 and the light-emitting element 300 between the electrode lines 210 and 220 may be aligned in each pixel PX. In the drawing, the pixels PX may be disposed in the first direction (the X-axis direction), which is a horizontal direction, and the second direction (the Y-axis direction), which is a longitudinal direction. Although FIG. 3 illustrates, in portion A, three sub-pixels PX1, PX2, and PX3, it is obvious that the display panel 10 may include a greater number of pixels PX or sub-pixels PX1, PX2, and PX3.

The first sub-pixel PX1, second sub-pixel PX2, and third sub-pixel PX3 of each pixel PX may be disposed in regions which are defined in the form of a matrix by the first electrode lines 210, the second electrode lines 220, and the data lines DL1 to DLm.

The pixel PX of FIG. 3 may be divided into pixels so that each of the pixels may constitute (or form) a pixel PX. As shown in FIG. 3, pixels are not necessarily disposed to be parallel in the first direction (the X-axis direction) and the second direction (the Y-axis direction) and may be disposed in various structures in which the pixels are disposed in a zigzag shape or the like.

The non-display area NDA may be defined as an area in which the pixels PX are not disposed and an area excluding the display area DA in the display panel 10. The non-display area NDA may be covered (or overlapped) by specific members so as not to be visually recognized from the outside of the display panel 10. Various members for driving the light-emitting elements 300 disposed in the display area DA may be disposed in the non-display area NDA. As shown in FIG. 3, in the display panel 10, pads DP, FP, and PP may be disposed on a side of the display area DA, for example, in the non-display area NDA located in an upper portion in a plan view.

The pads may include data pads DP (DP1, DP2, . . . , DPp, where p is a natural number), power pads PP (PP1, PP2), and floating pads FP (FP1, FP2). The data pads DP may be electrically connected to data lines DL extending to the pixels PX of the display area DA. The data pads DP may transmit data signals for driving the pixels PX to the pixels PX through the data lines DL. A data pad DP may be electrically connected to a data line DL, and the display panel 10 may include as many data pad DPs as the number of sub-pixels PXn disposed in the first direction (the X-axis direction) of the display area DA.

The data lines DL1 to DLm may extend (to be elongated) in the second direction (the Y-axis direction). One sides (or first sides) of the data lines DL1 to DLm may be electrically connected to the integrated driving circuit 20. Therefore, data voltages of the integrated driving circuit 20 may be applied to the data lines DL1 to DLm.

The first electrode lines 210 may be spaced from each other at predetermined intervals in the first direction (the X-axis direction). Therefore, the first electrode lines 210 may not overlap the data lines DL1 to DLm. In case that the display panel 10 is manufactured, the first electrode lines 210 are formed such that two end portions of an electrode line are respectively and electrically connected to a first floating line FL1 and a second floating line FL2 of the non-display area NDA and electrically disconnected in each pixel PX or each sub-pixel PXn.

Each of the second electrode lines 220 may extend in the first direction (the X-axis direction). Therefore, the second electrode lines 220 may overlap the data lines DL1 to DLm. Unlike the first electrode lines 210, the second electrode lines 220 may be electrically connected to the second voltage line QVSSL in the non-display area NDA. Therefore, the second voltages QVSS of the second voltage lines QVSSL may be applied to the second electrode lines 220.

In the non-display area NDA of the display panel 10, a pad portion PA including the data pads DP1 to DPp, the floating pads FP1 and FP2, and the power pads PP1 and PP2, the integrated driving circuit 20, the first floating line FL1, the second floating line FL2, and the second voltage lines QVSSL may be disposed.

The pad portion PA including the data pads DP1 to DPp, the floating pads FP1 and FP2, and the power pads PP1 and PP2 may be disposed on an edge of a side of the display panel 10, for example, on an edge of a lower side of the display panel 10. The data pads DP1 to DPp, the floating pads FP1 and FP2, and the power pads PP1 and PP2 may be disposed to be parallel in a first direction (the X-axis direction) in the pad portion PA.

The circuit board 40 may be bonded on the data pads DP1 to DPp, the floating pads FP1 and FP2, and the power pads PP1 and PP2 using an anisotropic conductive film. Therefore, the circuit board 40 may be electrically connected to the data pads DP1 to DPp, the floating pads FP1 and FP2, and the power pads PP1 and PP2.

The integrated driving circuit 20 may be electrically connected to the data pads DP1 to DPp through link lines LL. The integrated driving circuit 20 may receive digital video data DATA and timing signals through the data pads DP1 to DPp. The integrated driving circuit 20 may convert the digital video data DATA into analog data voltages and supply the analog data voltages to the data lines DL1 to DLm of the display panel 10.

The second voltage lines QVSSL may be electrically connected to the first power pad PP1 and the second power pad PP2 of the pad portion PA. The second voltage lines QVSSL may extend in the second direction (the Y-axis direction) in the non-display area NDA on a left outer side and a right outer side of the display area DA. The second voltage lines QVSSL may be electrically connected to the second electrode lines 220. Therefore, the second voltage QVSS of the power supply circuit 50 may be applied to the second electrode lines 220 through the circuit board 40, the first power pad PP1, the second power pad PP2, and the second voltage lines QVSSL.

The first floating line FL1 may be electrically connected to a first floating pad FP1 of the pad portion PA. The first floating line FL1 may extend in the second direction (the Y-axis direction) in the non-display area NDA on the left outer side and the right outer side of the display area DA.

The second floating line FL2 may be electrically connected to a second floating pad FP2 of the pad portion PA. The second floating line FL2 may extend in the second direction (the Y-axis direction) in the non-display area NDA on the left outer side and the right outer side of the display area DA. The first and second floating pads FP1 and FP2 and the first and second floating lines FL1 and FL2 may be dummy pads and dummy lines to which no voltage is applied.

The first floating line FL1 and the second floating line FL2 are lines for applying an alignment signal during a manufacturing process, and no voltage may be applied to the first floating line FL1 and the second floating line FL2 in the completed display device. As another example, a ground voltage may be applied to the first floating line FL1 and the second floating line FL2 so as to prevent static electricity in the completed display device.

Although not shown in the drawings, in the display panel 10, the first voltage line QVDDL for applying the first voltage QVDD to each pixel PX may be further disposed. A side of the first voltage line QVDDL may be electrically connected to another pad (not shown) to apply a voltage to each pixel PX or each sub-pixel PXn.

During the manufacturing process of the display panel 10, an electric field may be formed in each pixel PX or each sub-pixel PXn so as to align the light-emitting elements 300. Specifically, during the manufacturing process, a dielectrophoretic force may be applied to the light-emitting elements 300 using a dielectrophoretic method to align the light-emitting elements 300. Since the ground voltage is applied to the first electrode lines 210 and an alternating voltage (AC) is applied to the second electrode lines 220 to form an electric field in the pixel PX or the sub-pixel PXn, the light-emitting elements 300 may receive the dielectrophoretic force through the electric field to be aligned between electrodes.

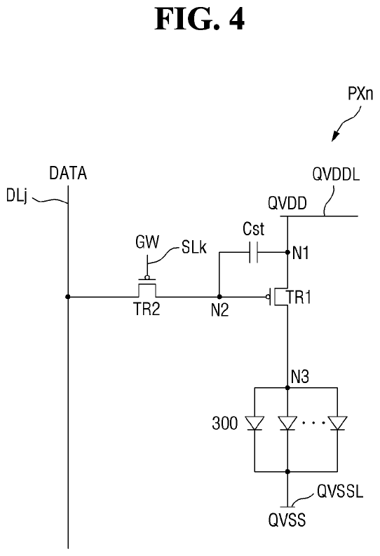

FIG. 4 is a schematic diagram of an equivalent circuit illustrating a pixel of FIG. 2.

Each of the first sub-pixel PX1, the second sub-pixel PX2, and the third sub-pixel PX3 may be electrically connected to at least one among the data lines DL1 to DLm, at least one among the scan lines SL1 to SLn, and the first voltage line QVDDL. The data lines DLj may transmit data signals to the sub-pixels PXn, a scan line SLk may transmit scan signals GW to the sub-pixels PXn, and the first voltage line QVDDL may transmit a driving current or an alignment signal to the sub-pixels PXn.

In this disclosure, the terms “first,” “second,” and the like are used to refer to each of components, but these are used to simply distinguish the components from each other and do not necessarily refer to a corresponding component. For example, the components defined as first, second, and the like are not necessarily limited to a specific structure or location and, in some cases, other numbers may be assigned to the components. Therefore, the number assigned to each component may be described through the drawings and the following description, and a first component mentioned below may be a second component within the technical idea of the disclosure.

Each of the first sub-pixel PX1, the second sub-pixel PX2, and the third sub-pixel PX3 may include the light-emitting elements 300, transistors for supplying a current to the light-emitting elements 300, and at least one capacitor.

The transistors may include a first transistor TR1 for applying a driving voltage to the light-emitting elements 300 and a second transistor TR2 for applying a data signal DATA to a gate electrode of the first transistor TR1.

FIG. 4 illustrates that the sub-pixel PXn has a two transistor-one capacitor (2T1C) structure having a first transistor TR1, a second transistor TR2, and a capacitor Cst, but the disclosure is not limited thereto. The sub-pixel PXn may include greater numbers of transistors and capacitors.

Each of the first and second transistors TR1 and TR2 may include a first electrode, a second electrode, and a gate electrode. One of the first electrode and the second electrode may be a source electrode, and the other thereof may be a drain electrode.

Each of the first and second transistors TR1 and TR2 may be formed of a thin film transistor. FIG. 4 illustrates that each of the first and second transistors TR1 and TR2 is formed of a p-type metal oxide semiconductor field effect transistor (MOSFET), but the disclosure is not limited thereto. Each of the first transistor TR1 and the second transistor TR2 may be formed of an n-type MOSFET. Positions of the source electrode and the drain electrode of each of the first transistor TR1 and the second transistor TR2 may be changed. Hereinafter, a case in which each of the first and second transistors TR1 and TR2 is formed of a P-type MOSFET will be described.

An end of the light-emitting element 300 is electrically connected to the first electrode line 210 of the display panel 10, and another end thereof is electrically connected to the second electrode line 220. As described below, one of the first electrode line 210 and the second electrode line 220 may be an anode electrode, and the other thereof may be a cathode electrode. However, the disclosure is not limited thereto, and the reverse may be possible. Hereinafter, a case in which the first electrode line 210 is an anode electrode and the second electrode line 220 is a cathode electrode will be described.

The first electrode line 210 electrically connected to the light-emitting element 300 may be electrically connected to a third node N3 of FIG. 4, and the second electrode line 220 may be electrically connected to the second voltage line QVSSL. The light-emitting element 300 may receive a predetermined current or a predetermined signal transmitted to a first node N1 through the third node N3.

The first transistor TR1 (or the driving transistor) may include a first electrode connected (or electrically connected) to the first node N1, a second electrode electrically connected to the first voltage line QVDDL, and a gate electrode electrically connected to a second node N2. The first transistor TR1 may provide a driving voltage applied from the first voltage line QVDDL to the light-emitting element 300 based on a voltage of the second node N2 (or a voltage stored in the capacitor Cst which will described below).

The second transistor TR2 (or a switching transistor) may include a first electrode electrically connected to the data line DLj (where j is an integer satisfying 1≤j≤m), a second electrode electrically connected to the second node N2, and a gate electrode electrically connected to the first scan line SLk (where k is an integer satisfying 1≤k≤n) which supplies a first scan signal GW. In response to the first scan signal GW, the second transistor TR2 may be turned on to transmit the data signal DATA, which is transmitted from the data line DLj to the first node N2.

The capacitor Cst may be electrically connected between the second node N2 and the first voltage line QVDDL. The capacitor Cst may store or maintain the data signal DATA which is provided.

Hereinafter, structures and arrangements of members disposed in each sub-pixel PXn will be described.

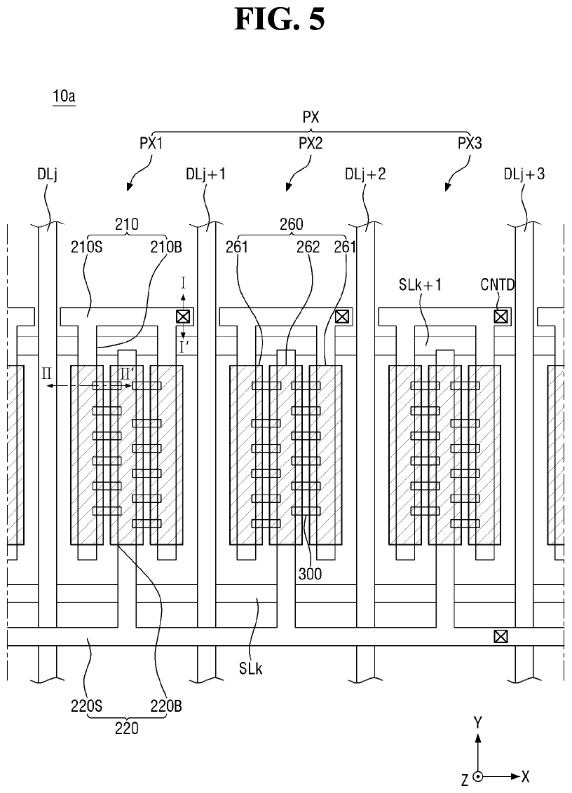

FIG. 5 is a schematic enlarged diagram of portion A of FIG. 3. FIG. 5 may be understood as an enlarged view by rotating portion A of FIG. 3 by as much as 180°.

Referring to FIG. 5, each pixel PX may include the first sub-pixel PX1, the second sub-pixel PX2, and the third sub-pixel PX3. The first sub-pixel PX1, second sub-pixel PX2, and third sub-pixel PX3 of each pixel PX may be disposed in the form of a matrix in regions defined by a cross structure of scan lines SLk and SLk+1 and data lines DLj, DLj+1, DLj+2, and DLj+3. The scan lines SLk and SLk+1 may extend in the first direction (the X-axis direction), and the data lines DLj, DLj+1, DLj+2, and DLj+3 may extend in the second direction (the Y-axis direction) intersecting the first direction (the X-axis direction).

Each of the first sub-pixel PX1, second sub-pixel PX2, and third sub-pixel PX3 may include the first electrode line 210, the second electrode line 220, and the light-emitting elements 300. The first electrode line 210 and the second electrode line 220 may be electrically connected to the light-emitting elements 300 and may each receive a voltage so as to allow the light-emitting elements 300 to emit light. Here, the voltage applied to allow the light-emitting elements 300 to emit light may be transmitted through the first transistor TR1 of FIG. 4.

At least a portion of each of the electrode lines 210 and 220 may be utilized to form an electric field in the pixel PX so as to align the light-emitting elements 300. The voltage applied to align the light-emitting elements 300 may be transmitted through the first transistor TR1 of FIG. 4.

Electrode lines 210 and 220 may include a first electrode line 210 and a second electrode line 220. In an example, the first electrode line 210 may be a pixel electrode which is separated for each pixel PX, and the second electrode line 220 may be a common electrode which is commonly connected along the pixels PX. One of the first electrode line 210 and the second electrode line 220 may be an anode electrode of the light-emitting element 300, and the other thereof may be a cathode electrode of the light-emitting element 300. However, the disclosure is not limited thereto, and the reverse may be possible.

The first electrode line 210 and the second electrode line 220 may include electrode stem portions 210S and 220S extending in the first direction (the X-axis direction) and at least one electrode branch portions 210B and 220B extending in the second direction (the Y-axis direction) intersecting the first direction and branching off from the electrode stem portions 210S and 220S.

Specifically, the first electrode line 210 may include the first electrode stem portion 210S extending in the first direction (the X-axis direction), and at least one first electrode branch portion 210B branching off from the first electrode stem portion 210S to extend in the second direction (the Y-axis direction).

The first electrode stem portion 210S of a pixel PX may be disposed substantially collinear with a first electrode stem portion 210S of an adjacent sub-pixel PXn (e.g., which is adjacent in the first direction (the X-axis direction) in a same row). In other words, two ends of the first electrode stem portion 210S of a pixel PX are spaced apart and terminated between the pixels PX, and a first electrode stem portion 210S of an adjacent pixel PX may be aligned with an extension line of the first electrode stem portion 210S of the pixel PX. Therefore, the first electrode stem portion 210S disposed in each pixel PXn may apply different electrical signals to first electrode branch portions 210B, and the first electrode branch portions 210B may be driven separately.

An arrangement of the first electrode stem portion 210S may be formed such that a stem electrode is formed during the manufacturing process and electrically disconnected by a laser or the like before the light-emitting elements 300 are aligned.

The first electrode branch portion 210B may branch off from at least a portion of the first electrode stem portion 210S and may extend in the second direction (the Y-axis direction). The first electrode branch portion 210B may be terminated in a state of being spaced apart from the second electrode stem portion 220S which is disposed to be opposite to the first electrode stem portion 210S.

One or more first electrode branch portions 210B may be disposed in each pixel PX. FIG. 5 illustrates that two first electrode branch portions 210B are disposed, and the second electrode branch portion 220B is disposed therebetween, but the disclosure is not limited thereto, and a greater number of first electrode branch portions 210B may be disposed. In some embodiments, the second electrode branch portion 220B is disposed between the first electrode branch portions 210B so that each sub-pixel PXn may have a symmetrical structure based on the second electrode branch portion 220B. However, the disclosure is not limited thereto.

The second electrode line 220 may include the second electrode stem portion 220S which extends in the first direction (the X-axis direction) and is spaced apart from and opposite to the first electrode stem portion 210S, and at least one second electrode branch portion 220B which branches off from the second electrode stem portion 220S, extends in the second direction (the Y-axis direction), and is spaced apart from and opposite to the first electrode branch portion 210B. However, an end portion (or an end) of the second electrode stem portion 220S may extend to adjacent pixels PXn in a first direction. Therefore, the two ends of the second electrode stem portion 220S of a pixel PX may be electrically connected to ends of second electrode stem portions 220S of adjacent pixels PX among the pixels PX.

The second electrode branch portion 220B may be spaced apart from and opposite to the first electrode branch portion 210B and terminated in a state of being spaced apart from the first electrode stem portion 210S. For example, an end portion of the second electrode branch portion 220B may be electrically connected to the second electrode stem portion 220S, and another end portion thereof may be disposed in the pixel PX in a state of being spaced apart from the first electrode stem portion 210S.

The first electrode branch portion 210B extends in a direction of the second direction (the Y-axis direction), and the second electrode branch portion 220B extends in another direction of the second direction (the Y-axis direction) so that the one end portions of the branch portions may be disposed in opposite directions based on a central portion of the pixel PX. However, the disclosure is not limited thereto, and the first electrode stem portion 210S and the second electrode stem portion 220S may be spaced apart from each other in a same direction based on the central portion of the pixel PX. The first electrode branch portion 210B and the second electrode branch portion 220B branching off from the first and second electrode stem portions 210S and 220S, respectively, may extend in a same direction.

The light-emitting elements 300 may be disposed between the first electrode branch portion 210B and the second electrode branch portion 220B. One end portions (or first end portions) of at least some of the light-emitting elements 300 may be electrically connected to the first electrode branch portion 210B, and other ends thereof may be electrically connected to the second electrode branch portion 220B.

The light-emitting elements 300 may be spaced apart from each other in the second direction (the Y-axis direction) and disposed substantially parallel to each other. A gap between the light-emitting elements 300 is not particularly limited. In some cases, the light-emitting elements 300 may be disposed adjacent to each other to form a group, and other light-emitting elements 300 may be grouped in a state of being spaced from each other at regular intervals, may have a nonuniform density, and may be oriented and aligned in a direction.

A contact electrode 260 may be disposed on each of the first electrode branch portion 210B and the second electrode branch portion 220B.

Contact electrodes 260 may extend in the second direction (the Y-axis direction) and may be spaced apart from each other in the first direction (the X-axis direction). The contact electrode 260 may contact at least an end portion of the light-emitting element 300, and the contact electrode 260 may contact the first electrode line 210 or the second electrode line 220 to receive an electrical signal. Therefore, the contact electrode 260 may transmit an electrical signal, which is transmitted from each of the electrode lines 210 and 220, to the light-emitting element 300.

The contact electrode 260 may be disposed on each of the electrode branch portions 210B and 220B to partially cover (or overlap) the electrode branch portions 210B and 220B and may include a first contact electrode 261 and a second contact electrode 262 which contact an end portion or another end portion of the light-emitting element 300.

The first contact electrode 261 may be disposed on the first electrode branch portion 210B and may contact an end portion of the light-emitting element 300 which is electrically connected to the first electrode line 210. The second contact electrode 262 may be disposed on the second electrode branch portion 220B and may contact another end portion of the light-emitting element 300 which is electrically connected to the second electrode line 220.

In some embodiments, the two end portions of the light-emitting element 300 electrically connected to the first electrode branch portion 210B or the second electrode branch portion 220B may be conductive semiconductor layers doped with an n-type or p-type dopant. In case that an end portion of the light-emitting element 300 electrically connected to the first electrode branch portion 210B is a conductive semiconductor layer doped with a p-type dopant, another end of the light-emitting element 300 electrically connected to the second electrode branch portion 220B may be a conductive semiconductor layer doped with an n-type dopant. However, the disclosure is not limited thereto, and the reverse may be possible.

The first electrode stem portion 210S may be electrically connected to the first transistor TR1, which will be described below, through an electrode contact hole CNTD. Although not shown in the drawings, the second electrode stem portion 220S may be electrically connected to the second voltage line QVSSL through an electrode contact hole located in the non-display area NDA. Unlike the first electrode stem portion 210S, in each sub-pixel PXn, a separate electrode contact hole may be omitted from the second electrode stem portion 220S. However, the disclosure is not limited thereto, and an electrode contact hole may be formed even in the second electrode stem portion 220S so that the second electrode stem portion 220S may be electrically connected to the second voltage line QVSSL.

FIG. 5 illustrates only a schematic plan view in which the first electrode line 210, the second electrode line 220, and the light-emitting elements 300 of the display panel 10 are disposed. However, as described below, the first electrode line 210 and the second electrode line 220 of the display panel 10 may be electrically connected to members disposed in a circuit element layer which is located below the first electrode line 210 and the second electrode line 220. The members disposed in the circuit element layer may form elements including a semiconductor layer and conductive layers.

Hereinafter, a specific configuration of the display panel 10 will be described in detail with reference to a schematic plan view and a schematic cross-sectional view of the display panel 10.

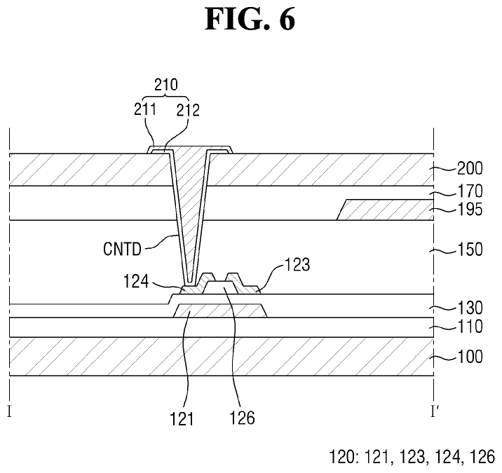

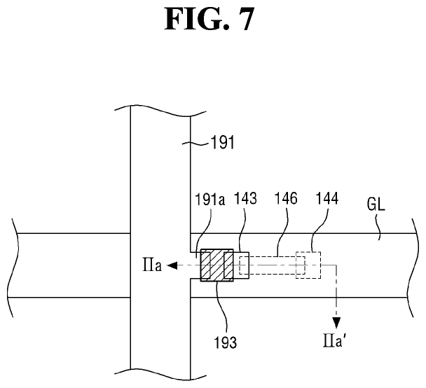

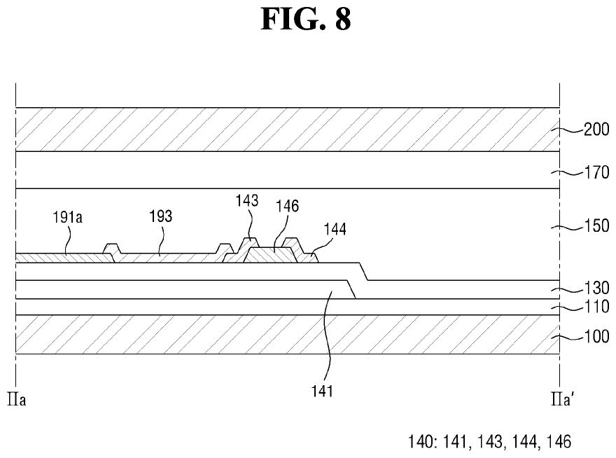

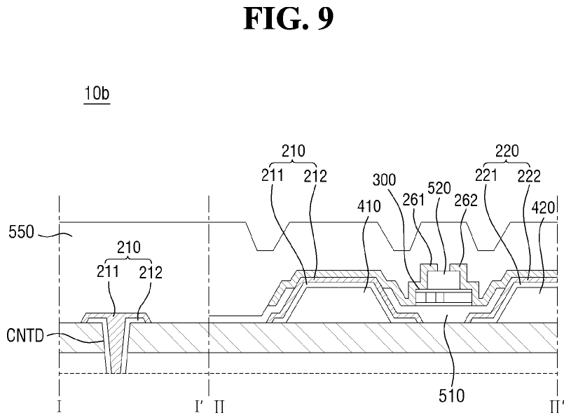

FIG. 6 is a schematic cross-sectional view illustrating a circuit element layer taken along line I-I′ of FIG. 5. FIG. 7 is a schematic partial plan view illustrating the circuit element layer according to an embodiment, and FIG. 8 is a schematic cross-sectional view taken along line IIa-IIa′ of FIG. 7. FIG. 9 is a schematic cross-sectional view illustrating the display element layer taken along lines I-I′ and II-II′ of FIG. 5.

According to an embodiment, the display panel 10 may include a circuit element layer 10a and a display element layer 10b. The circuit element layer 10a may include the first and second transistors TR1 and TR2 and the capacitor Cst, which are described with reference to FIG. 4, and the display element layer 10b may include the first electrode line 210, the second electrode line 220, and the light-emitting element 300. The drawings illustrate only a layout diagram with respect to a sub-pixel PXn, but it is obvious that other sub-pixels PXn have a same layout. Hereinafter, a description will be made based on a sub-pixel PXn.

In the following description, even in case that some components are substantially identical or similar to those mentioned in FIGS. 1 to 4, in order to easily describe an arrangement and a coupling relationship between the components, new reference numerals are assigned to these components.

Lines I-I′ and II-II′ of FIG. 6 may correspond to lines I-I′ and II-II′ of FIG. 5, respectively. For example, it may be understood that the cross-sectional view shown in FIG. 6 illustrates components located in the circuit element layer 10a of the plan view of FIG. 5. Lines I-I′ and II-II′ of FIG. 9 correspond to lines I-I′ and II-II′ of FIG. 5, and it may be understood that FIG. 9 partially illustrates components located in the display element layer 10b. Hereinafter, members of the display panel 10 will be described in detail with reference to FIGS. 5 to 9.

Referring to FIGS. 5 to 9, the circuit element layer 10a may include a first transistor 120, a second transistor 140, a data line 191, a conductive pattern 193, a voltage line 195, and a via layer 200.

The display element layer 10b may be disposed on the via layer 200 and may include banks 410 and 420, reflective layers 211 and 221, electrode layers 212 and 222, a first insulating layer 510, a first contact electrode 261, a second contact electrode 262, a second insulating layer 520, and a passivation layer 550. The reflective layer 211 and the electrode layer 212 may form the electrode 210, and the reflective layer 221 and the electrode layers 222 may form the electrode 220.

Each of the above-described layers may be formed of a single layer or may also be formed of a stacked layer including layers. Another layer may be further disposed between the above-described layers. In particular, the circuit element layer 10a is not limited to the structure shown in FIGS. 6 to 8, and a greater number of conductive layers, insulating layers, and signal lines may be further disposed in the circuit element layer 10a.

Hereinafter, the circuit element layer 10a of the display panel 10 will be described with reference to FIGS. 6 to 8, and then the display element layer 10b will be described with reference to FIGS. 5 and 9.

Referring first to FIGS. 6 to 8, a substrate 100 supports layers disposed thereon. The substrate 100 may be an insulating substrate made of (or include) an insulating material such as glass, quartz, a polymer resin, or the like. Examples of a polymer material may include polyethersulphone (PES), polyacrylate (PA), polyarylate (PAR), polyetherimide (PEI), polyethylene napthalate (PEN), polyethylene terepthalate (PET), polyphenylene sulfide (PPS), polyallylate, polyimide (PI), polycarbonate (PC), cellulose triacetate (CAT), cellulose acetate propionate (CAP), and a combination thereof. The substrate 100 may include a metal material.

The substrate 100 may be a rigid substrate or a flexible substrate which is bendable, foldable, rollable, and the like. However, the disclosure is not limited thereto.

A buffer layer 110 may be disposed on the substrate 100. The buffer layer 110 may prevent diffusion of impurity ions and permeation of water or outdoor air and perform a surface planarization function. The buffer layer 110 may include silicon nitride, silicon oxide, silicon oxynitride, or the like. Other layers may be further disposed between the substrate 100 and the buffer layer 110.

The first transistor 120 (121, 123, 124, and 126) and the second transistor 140 (141, 143, 144, and 146) are disposed on the substrate 100. The first transistor 120 may be a driving transistor for driving the display element layer 10b as the first transistor TR1 of FIG. 4, and the second transistor 140 may be a switching transistor for transmitting the data signal DATA to the first transistor TR1 as the second transistor TR2 of FIG. 4.

The first transistor 120 includes a first gate electrode 121, a first active layer 126, a first source electrode 123, and a first drain electrode 124. The second transistor 140 includes a second gate electrode 141, a second active layer 146, a second source electrode 143, and a second drain electrode 144.

The first gate electrode 121 and the second gate electrode 141 are disposed on the buffer layer 110. The first gate electrode 121 may constitute a gate electrode of the first transistor 120, and the second gate electrode 141 may constitute a gate electrode of the second transistor 140. Each of the first gate electrode 121 and the second gate electrode 141 may be formed of a conductive metal layer. For example, each of the first gate electrode 121 and the second gate electrode 141 may include one or more metals selected from among molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), and copper (Cu).

A first gate insulating film 130 is disposed on the first gate electrode 121 and the second gate electrode 141. The first gate insulating film 130 may be a gate insulating film having a gate insulating function. The first gate insulating film 130 may include a silicon compound, metal oxide, or the like. For example, the first gate insulating film 130 may include silicon oxide, silicon nitride, silicon oxynitride, aluminum oxide, tantalum oxide, hafnium oxide, zirconium oxide, titanium oxide, or the like. These may be used alone or in combination. The first gate insulating film 130 may be a single layer or a multi-layer made of stacked layers of different materials.

The first active layer 126 and the second active layer 146 are disposed on the first gate insulating film 130. The first active layer 126 and the second active layer 146 may be active layers forming channels of the first transistor 120 and the second transistor 140. Each of the first active layer 126 and the second active layer 146 may include a channel region.

The first active layer 126 may overlap the first gate electrode 121 with the first gate insulating film 130 interposed therebetween, and an overlapping region therebetween may form a first channel region. The second active layer 146 may overlap the second gate electrode 141 with the first gate insulating film 130 interposed therebetween, and an overlapping region therebetween may form a second channel region.

Each of the first active layer 126 and the second active layer 146 may be made of an oxide semiconductor. The oxide semiconductor may include a binary compound (ABₓ), a ternary compound (ABₓC_{y}), or a tetra compound (ABₓC_{y}D_{z}), which include indium (In), zinc (Zn), gallium (Ga), tin (Sn), Ti, Al, hafnium (Hf), zirconium (Zr), Mg, and the like. In an embodiment, the oxide semiconductor may include an indium tin zinc oxide (ITZO) (which is an oxide including In, Sn, and Ti) or indium gallium zinc oxide (IGZO) (which is an oxide including In, Ga, and Sn). For example, according to an embodiment, each of the first transistor 120 and the second transistor 140 may have a bottom-gate structure in which a channel region is disposed above the first and second gate electrodes 121 and 141, and the channel region may include an oxide semiconductor. Therefore, in case that the display device 1 is manufactured, the cost of manufacturing the circuit element layer 10a may be reduced.

The first source/drain electrodes 123 and 124 and the second source/drain electrodes 143 and 144 are disposed on the first active layer 126 and the second active layer 146 on the first gate insulating film 130. The first source electrode 123 is disposed on a side of the first active layer 126, and the first drain electrode 124 is disposed on another side of the first active layer 126. The second source electrode 143 is disposed on a side of the second active layer 146, and the second drain electrode 144 is disposed on another side of the second active layer 146. Each of the first source/drain electrodes 123 and 124 and the second source/drain electrodes 143 and 144 may include one or more metals selected from among Mo, Al, Pt, Pd, Ag, Mg, Au, Ni, Nd, Ir, Cr, Ca, Ti, Ta, W, and Cu.

The data line 191 and the conductive pattern 193 may be further disposed on the first gate insulating film 130. The data line 191 may transmit a data signal (hereinafter referred to as a “data signal DATA” in FIG. 4). A side of the conductive pattern 193 is disposed on the data line 191, and another side thereof is disposed on the second source electrode 143 of the second transistor 140. The second transistor 140 may receive the data signal DATA transmitted to the data line 191 through the conductive pattern 193.

Specifically, referring to FIGS. 5, 7, and 8, the data line 191 may extend in a direction. As shown in FIG. 5, the data line 191 may extend in the second direction (the Y-axis direction) and cross the boundary of the pixel PX or the sub-pixel PXn to extend to an adjacent pixel PX or sub-pixel PX. The data line 191 may be disposed on one side of one pixel or one sub-pixel, for example, disposed adjacent to a left of one pixel or one sub-pixel.

A gate line GL may extend in a direction and may partially overlap the data line 191. The gate line GL may extend in the first direction (the X-axis direction) and overlap the data line 191 which extends in the second direction (the Y-axis direction). According to an embodiment, the data line 191 may include a protrusion 191a protruding in the first direction (the X-axis direction) in a region thereof overlapping the gate line GL.

The protrusion 191a of FIG. 7 may be the data line 191 of FIG. 8. The protrusion 191a of the data line 191 may protrude in the first direction (the X-axis direction) and may be spaced apart from the second source electrode 143 of the second transistor 140 and terminated. The protrusion 191a of the data line 191 and the second source electrode 143 of the second transistor 140 may be spaced apart from each other, and the conductive pattern 193 may be disposed between the protrusion 191a and the second source electrode 143.

The data line 191, the conductive pattern 193, and the second source electrode 143 may include a same material. For example, the conductive pattern 193 may include a conductive metal material and may electrically connect the data line 191 to the second source electrode 143. The data signal DATA transmitted from the data line 191 may be transmitted to the second source electrode 143 of the second transistor 140 through the protrusion 191a and the conductive pattern 193.

A first protection film 150 is disposed on the first source/drain electrodes 123 and 124, the second source/drain electrodes 143 and 144, the data line 191, and the conductive pattern 193. The first protection film 150 may be formed of an inorganic layer, for example, a silicon oxide film (SiOₓ), a silicon nitride film (SiNₓ), or a multi-layer thereof.

The voltage line 195 is disposed on the first protection film 150. Although not shown in the drawings, the voltage line 195 may be electrically connected to the first transistor 120 to transmit a voltage signal QVDD or QVSS (see FIG. 4) thereto. The voltage line 195 may extend in a direction. The voltage line 195 may extend in the second direction (the Y-axis direction) and cross the boundary of the pixel PX or the sub-pixel PXn to extend to an adjacent pixel PX or sub-pixel PX. The voltage line 195 may be disposed on a side of a pixel or a sub-pixel, for example, disposed adjacent to a right side of a pixel or a sub-pixel.

A second protection film 170 is disposed on the voltage line 195 and the first protection film 150. The second protection film 170 may cover (or overlap) the voltage line 195 and other members not shown in the drawings. The second protection film 170 and the first protection film 150 may perform substantially a same function.

The via layer 200 may be formed on the second protection film 170. The via layer 200 may cover (or overlap) an entirety of the circuit element layer 10a and may perform a function of supporting members of the display element layer 10b, which will be described below. The via layer 200 may perform a function of planarizing a step due to the first and second transistors 120 and 140 of the circuit element layer 10a and the voltage line 195. The via layer 200 may be formed of an organic film such as an acrylic resin, an epoxy resin, a phenolic resin, a polyamide resin, or a polyimide resin.

As described below, the first drain electrode 124 of the first transistor 120 may be electrically connected to the first electrode line 210 of the display element layer 10b, which will be described below, through the electrode contact hole CNTD passing through the via layer 200, the second protection film 170, and the first protection film 150. The first transistor 120 may be electrically connected to the voltage line 195 and the second drain electrode 144 of the second transistor 140 and may transmit an electrical signal to the first electrode line 210 of the display element layer 10b.

FIGS. 6 to 8 illustrate only some members of the circuit element layer 10a, and the embodiment is not limited thereto. The circuit element layer 10a may include a greater number of members not shown in the drawings.

The display element layer 10b will be described with reference to FIGS. 5 and 9.

Banks 410 and 420 are disposed on the via layer 200. The banks 410 and 420 may be disposed in each sub-pixel PXn to be separated from each other. The banks 410 and 420 may include a first bank 410 and a second bank 420 which are disposed adjacent to a central portion of the sub-pixel PXn, and a third bank disposed at a boundary between the sub-pixels PXn.

In case that an ink I is sprayed using an inkjet printing device during the manufacturing of the display panel 10, the third bank may perform a function of blocking the ink from crossing a boundary of the sub-pixel PXn. In case that the display panel 10 further includes other members, the other members may be disposed on the third bank, and the third bank may perform a function of supporting the other members. However, the disclosure is not limited thereto.

The first bank 410 and the second bank 420 are separated from and opposite to each other. The first electrode line 210 may be disposed on the first bank 410, and the second electrode line 220 may be disposed on the second bank 420. Referring to FIGS. 5 and 9, it may be understood that the first electrode branch portion 210B is disposed on the first bank 410, and the second electrode branch portion 220B is disposed on the second bank 420.

As described above, the first bank 410, the second bank 420, and the third bank may be formed by substantially a same process. Thus, the banks 410 and 420 may constitute a single grid pattern. Each of the banks 410 and 420 may include polyimide (PI).

Each of the banks 410 and 420 may have a structure in which at least a portion thereof protrudes from the via layer 200. The banks 410 and 420 may protrude upward from a flat surface on which the light-emitting element 300 is disposed, and at least a part of each of the protruding portions may have a slope. A shape of each of the banks 410 and 420 having the protruding structures is not particularly limited. As shown in the drawings, the first bank 410 and the second bank 420 protrude to a same height, and the third bank may have a shape protruding to a higher position.

Reflective layers 211 and 221 may be disposed on the first bank 410 and the second bank 420, and electrode layers 212 and 222 may be disposed on the reflective layers 211 and 221. The reflective layer 211 and the electrode layer 212 may form the electrode 21, and the reflective layer 221 and the electrode layer 222 may form the electrode 22.

The reflective layers 211 and 221 include a first reflective layer 211 and a second reflective layer 221. The first reflective layer 211 may cover (or overlap) the first bank 410, and the second reflective layer 221 may cover the second bank 420. Portions of the reflective layers 211 and 221 are electrically connected to the circuit element layer 10a through a contact hole passing through the via layer 200.

Each of the reflective layers 211 and 221 may include a material having high reflectance to reflect light emitted from the light-emitting element 300. For example, each of the reflective layers 211 and 221 include a material such as Ag, Cu, ITO, IZO, or ITZO, but the disclosure is not limited thereto.

The electrode layers 212 and 222 include a first electrode layer 212 and a second electrode layer 222. The electrode layers 212 and 222 and the reflective layers 211 and 221 may have substantially same patterns. The first reflective layer 211 and the first electrode layer 212 are spaced apart from the second reflective layer 221 and the second electrode layer 222.

Each of the electrode layers 212 and 222 includes a transparent conductive material, and thus light emitted from the light-emitting element 300 may be incident on the reflective layers 211 and 221. For example, each of the electrode layers 212 and 222 may include a material such as ITO, IZO, or ITZO, but the disclosure is not limited thereto.

In some embodiments, the reflective layers 211 and 221 and the electrode layers 212 and 222 may form a structure in which one or more transparent conductive layers including ITO, IZO, or ITZO, and one or more metal layers including Ag or Cu are stacked. For example, the reflective layers 211 and 221 and the electrode layers 212 and 222 may form a stacked structure of ITO/Ag/ITO/IZO.

In some embodiments, the first electrode line 210 and the second electrode line 220 may be formed as a single layer. For example, the reflective layers 211 and 221 and the electrode layers 212 and 222 may be formed as a single layer to transmit an electrical signal to the light-emitting element 300 and, simultaneously, reflect light. For example, each of the first electrode line 210 and the second electrode line 220 may include an alloy including Al, Ni, and lanthanum (La) as a conductive material having high reflectance. However, the disclosure is not limited thereto.

The first insulating layer 510 may partially cover (or overlap) the first electrode line 210 and the second electrode line 220. The first insulating layer 510 may cover most of upper surfaces of the first electrode line 210 and the second electrode line 220 and may expose portions of the first electrode line 210 and the second electrode line 220. The first insulating layer 510 may partially cover an area in which the first electrode line 210 is spaced apart from the second electrode line 220 and an area opposite to the area in which the first electrode line 210 is spaced apart from the second electrode line 220.

The first insulating layer 510 may expose relatively flat upper surfaces of the first electrode line 210 and the second electrode line 220 and allow the electrode lines 210 and 220 to overlap inclined surfaces of the first bank 410 and the second bank 420. The first insulating layer 510 may have a flat upper surface to allow the light-emitting element 300 to be disposed thereon, and the flat upper surface may extend toward the first electrode line 210 and the second electrode line 220 in a direction. An extension portion of the first insulating layer 510 is terminated at inclined surfaces of the first electrode line 210 and the second electrode line 220. Therefore, the contact electrodes 260 may electrically contact the exposed first electrode line 210 and the exposed second electrode line 220 and may smoothly contact the light-emitting element 300 on the flat upper surface of the first insulating layer 510.

The first insulating layer 510 may protect the first electrode line 210 and the second electrode line 220 and, simultaneously, insulate the first electrode line 210 from the second electrode line 220. The first insulating layer 510 may prevent the light-emitting element 300 disposed thereon from being damaged by directly contacting other members.

The light-emitting element 300 may be disposed on the first insulating layer 510. At least one light-emitting element 300 may be disposed on the first insulating layer 510 between the first electrode line 210 and the second electrode line 220. The light-emitting element 300 may include layers disposed in a direction horizontal to the via layer 200.

The light-emitting element 300 of the display panel 10 according to an embodiment may include the conductive semiconductors and the active layer, which are described above, and the conductive semiconductors and the active layer may be sequentially disposed on the via layer 200 in a horizontal direction. As shown in the drawings, in the light-emitting element 300, a first conductivity type semiconductor 310, an active material layer (or active layer) 330, a second conductivity type semiconductor 320, and a conductive electrode layer 370 may be sequentially disposed in a direction horizontal to the via layer 200. However, the disclosure is not limited thereto. The order of the layers disposed in the light-emitting element 300 may be reversed. In case that the light-emitting element 300 has another structure, the layers may be disposed in a direction perpendicular to the via layer 200.

The second insulating layer 520 may be partially disposed on the light-emitting element 300. The second insulating layer 520 may protect the light-emitting element 300 and, simultaneously, perform a function of fixing the light-emitting element 300 during a process of manufacturing the display panel 10. The second insulating layer 520 may surround an outer surface of the light-emitting element 300. For example, a portion of a material of the second insulating layer 520 may be disposed between a bottom surface of the light-emitting element 300 and the first insulating layer 510. The second insulating layer 520 may extend between the first electrode branch portion 210B and the second electrode branch portion 220B in the second direction to have an island shape or a linear shape in a plan view.

The contact electrodes 260 are disposed on the electrode lines 210 and 220 and the second insulating layer 520. The first contact electrode 261 and the second contact electrode 262 are disposed on the second insulating layer 520 to be spaced apart from each other. Therefore, the second insulating layer 520 may insulate the first contact electrode 261 from the second contact electrode 262.

The first contact electrode 261 may electrically contact at least the first electrode line 210, which is exposed by patterning of the first insulating layer 510, and at least one end of the light-emitting element 300. The second contact electrode 262 may electrically contact at least the second electrode line 220, which is exposed by the patterning of the first insulating layer 510, and at least another end of the light-emitting element 300. The first and second contact electrodes 261 and 262 may contact side surfaces of the two end portions of the light-emitting element 300, for example, the first conductivity type semiconductor 310, the second conductivity type semiconductor 320, or the conductive electrode layer 370. As described above, the first insulating layer 510 has the flat upper surface so that the contact electrode 260 may smoothly contact the side surfaces of the light-emitting element 300.

The contact electrode 260 may include a conductive material. For example, the contact electrode 260 may include ITO, IZO, ITZO, or Al. However, the disclosure is not limited thereto.

The passivation layer 550 may be formed on the second insulating layer 520 and the second contact electrode 262 and may perform a function of protecting the members of the display element layer 10b from an external environment.

Each of the first insulating layer 510, the second insulating layer 520, and the passivation layer 550, which are described above, may include an inorganic insulating material or an organic insulating material. In an example, each of the first insulating layer 510 and the passivation layer 550 may include a material such as SiOₓ, SiNₓ, SiOₓN_{y}, Al₂O₃, aluminum nitride (AlN), or the like. The second insulating layer 520 may be made of an organic insulating material including a photoresist or the like. However, the disclosure is not limited thereto.

Hereinafter, the circuit element layer 10a of the display panel 10 according to an embodiment will be described.

FIGS. 5 to 9 illustrate the above-described display panel 10 including the first and second transistors 120 and 140 of the circuit element layer 10a, which have a structure in which the first and second active layers 126 and 146, each having a channel region, are formed above the first and second gate electrodes 121 and 141. However, the disclosure is not limited thereto, and for example, the first and second transistors 120 and 140 may have other structures in which the first and second active layers 126 and 146 are formed below the first and second gate electrodes 121 and 141 or further include other conductive layers.

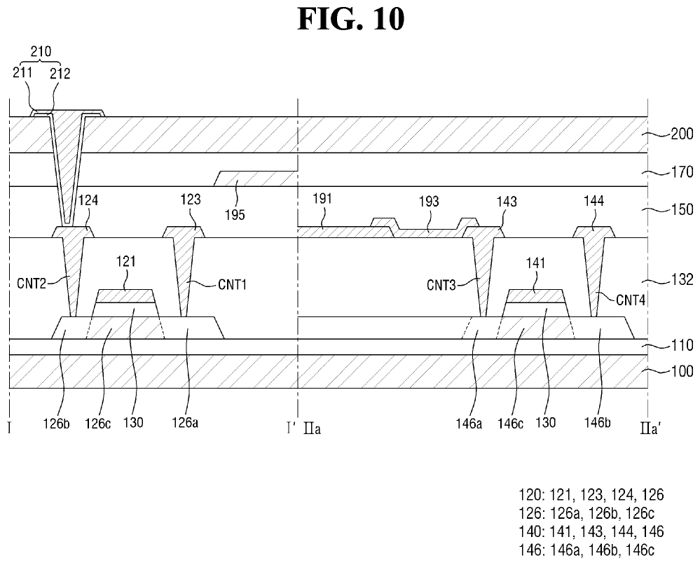

FIG. 10 is a schematic cross-sectional view illustrating a circuit element layer according to an embodiment.

Referring to FIG. 10, first and second gate electrodes 121 and 141 are formed on first and second active layers 126 and 146 including channel regions in a first transistor 120 and a second transistor 140. For example, each of the first and second transistors 120 and 140 may have a top-gate structure.

The first active layer 126 and the second active layer 146 are disposed on a buffer layer 110. The first active layer 126 and the second active layer 146 may include first conductorized regions 126a and 146a, second conductorized regions 126b and 146b, and channel regions 126c and 146c, respectively. The channel regions 126c and 146c may be disposed between the first conductorized regions 126a and 146a and the second conductorized regions 126b and 146b. As described above, each of the first and second active layers 126 and 146 may be an oxide semiconductor.

A first gate insulating film 130 is disposed on the first active layer 126 and the second active layer 146. The first and second gate electrodes 121 and 141 are disposed on the first gate insulating film 130. The first active layer 126 may overlap the first gate electrode 121 with the first gate insulating film 130 interposed therebetween, and the first channel region 126c is formed in the overlapping region. The second active layer 146 may overlap the second gate electrode 141 with the first gate insulating film 130 interposed therebetween, and the second channel region 146c is formed in the overlapping region.

In the drawings, although the first gate insulating film 130 is disposed only between the first and second gate electrodes 121 and 141 and the first and second active layers 126 and 146, the disclosure is not limited thereto. For example, as shown in FIG. 6, the first gate insulating film 130 may be disposed on an entirety of the buffer layer 110, including the first and second active layers 126 and 146.

An interlayer insulating film 132 may be disposed on the first and second gate electrodes 121 and 141 and may cover (or overlap) an entirety of the first and second active layers 126 and 146 and the buffer layer 110. A first contact hole CNT1 passing through the interlayer insulating film 132 to expose a portion of an upper surface of the first active layer 126, and a second contact hole CNT2 exposing another portion of the upper surface thereof are formed in the interlayer insulating film 132. A third contact hole CNT3 passing through the interlayer insulating film 132 to expose a portion of an upper surface of the second active layer 146, and a fourth contact hole CNT4 exposing another portion of the upper surface thereof may be formed in the interlayer insulating film 132. The first contact hole CNT1 may expose a first conductorized region 126a of the first active layer 126, the second contact hole CNT2 may expose a second conductorized region 126b of the first active layer 126, the third contact hole CNT3 may expose a first conductorized region 146a of the second active layer 146, and the fourth contact hole CNT4 may expose a second conductorized region 146b of the second active layer 146.

First source/drain electrodes 123 and 124 and second source/drain electrodes 143 and 144 may be disposed on the interlayer insulating film 132. The first source electrode 123 may electrically contact the first conductorized region 126a formed on a side of the first active layer 126 through the first contact hole CNT1. The first drain electrode 124 may electrically contact the second conductorized region 126ba formed on another side of the first active layer 126 through the second contact hole CNT2. The second source electrode 143 contacts the first conductorized region 146a formed on a side of the second active layer 146 through the third contact hole CNT3. The second drain electrode 144 may electrically contact the second conductorized region 146b formed on another side of the second active layer 146 through the fourth contact hole CNT4.

According to an embodiment, in the first transistor 120 and the second transistor 140, first and second gate electrodes 121 and 141 may be respectively formed on the first and second active layers 126 and 146, and the first and second active layers 126 and 146 may include oxide semiconductors, and thus the channel regions 126c and 146c may be formed thereon. Descriptions of other members are the same as described above, and thus will be omitted herein.

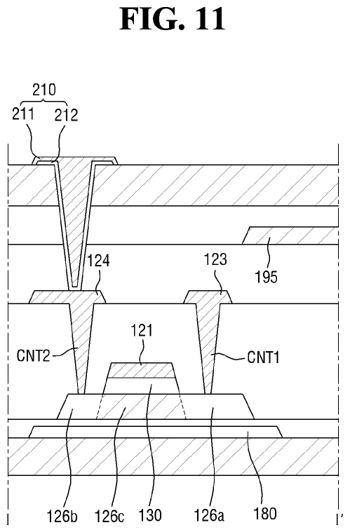

FIG. 11 is a schematic cross-sectional view illustrating a circuit element layer according to an embodiment.

Referring to FIG. 11, a circuit element layer 10a according to an embodiment may further include a light blocking layer 180 disposed between a substrate 100 and a buffer layer 110. FIG. 11 illustrates only a first transistor 120, but this may be equally applied to a second transistor 140.

At least one light blocking layer 180 may be disposed on the substrate 100. The light blocking layer 180 may be disposed between the substrate 100 and the buffer layer 110 and may perform a function of blocking light incident on a first active layer 126 from the substrate 100. The light blocking layer 180 may overlap the first active layer 126 disposed on the buffer layer 110. For example, an area in which the light blocking layer 180 is disposed to cover (or overlap) the first active layer 126 may be greater than an area of the first active layer 126. The light blocking layer 180 may include a material which absorbs incident light or blocks transmission of the incident light. For example, the light blocking layer 180 may be formed of a single layer or a multi-layer made of (or including) at least one of Mo, Al, Cr, Au, Ti, Ni, Nd, and Cu, and an alloy thereof.

The first transistor 120 and the second transistor 140 may have different structures and may be disposed on different layers.

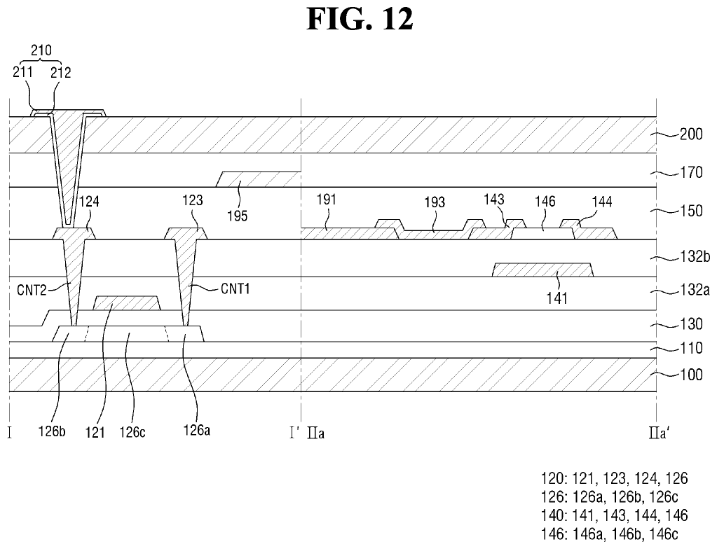

FIG. 12 is a schematic cross-sectional view illustrating a circuit element layer according to an embodiment.

Referring to FIG. 12, in a circuit element layer 10a according to an embodiment, interlayer insulating films 132a and 132b are disposed on a first active layer 126 of a first transistor 120, and a second gate electrode 141 of a second transistor 140 is disposed between the interlayer insulating films 132a and 132b. The interlayer insulating films 132a and 132b may include a first interlayer insulating film 132a and a second interlayer insulating film 132b, and the first interlayer insulating film 132a and the second interlayer insulating film 132b may be sequentially disposed on the first active layer 126. The second gate electrode 141 is disposed on the first interlayer insulating film 132a, and a second active layer 146 is disposed on the second interlayer insulating film 132b.

FIG. 12 illustrates that the first transistor 120 has a structure in which the first gate electrode 121 is formed on the first active layer 126 and may have a shape substantially identical or similar to that of the first transistor 120 of FIG. 10. The first transistor 120 of FIG. 12 may be identical or similar to the first transistor 120 of FIG. 10, except that the first contact hole CNT1 and the second contact hole CNT2 exposing the first conductorized region 126a and the second conductorized region 126b pass through the first and second interlayer insulating films 132a and 132b.

The first active layer 126 of the first transistor 120 may include other semiconductor materials in addition to the oxide semiconductor. For example, the first active layer 126 may include polycrystalline silicon. The polycrystalline silicon may be formed by crystallizing amorphous silicon. Examples of the crystallization method may include a rapid thermal annealing (RTA) method, a solid phase crystallization (SPC) method, an excimer laser annealing (ELA) method, a metal induced crystallization (MIC) method, a metal induced lateral crystallization (MILC) method, a sequential lateral solidification (SLS) method, and the like, but the disclosure is not limited thereto. As another example, the first active layer 126 may include monocrystalline silicon, low temperature polycrystalline silicon, amorphous silicon, or the like. However, the disclosure is not limited thereto.

Hereinafter, a detailed description of the first transistor 120 will be omitted herein, and the second transistor 140 will be described.

The second transistor 140 may include the second gate electrode 141 disposed on the first interlayer insulating film 132a, the second active layer 146 disposed on the second interlayer insulating film 132b, and the second source/drain electrodes 143 and 144. The data line 191 to which the data signal DATA is applied and the conductive pattern 193 connecting the data line 191 to the second source electrode 143 may also be disposed on the second interlayer insulating film 132b.

The first active layer 126, the second active layer 146, the first gate electrode 121, and the second gate electrode 141 may be disposed on different layers. The first active layer 126 and the second active layer 146, each including a semiconductor, may constitute a lower semiconductor layer and an upper semiconductor layer in the circuit element layer 10a.

The first transistor 120 and the second transistor 140 may be formed of different types of transistors. In the above description, although the first and second transistors 120 and 140 have been described as being formed as p-type MOSFETs, at least one of the first and second transistors 120 and 140 may be formed as an n-type MOSFET. One of the first and second transistors 120 and 140 may be formed as a p-type MOSFET, and the other thereof may be formed as an n-type MOSFET. Detailed descriptions of other members will be omitted herein.

The light-emitting element 300 may include a semiconductor crystal to emit light in a specific wavelength range. The light-emitting element 300 may emit light toward an upper portion of the display element layer 10b.

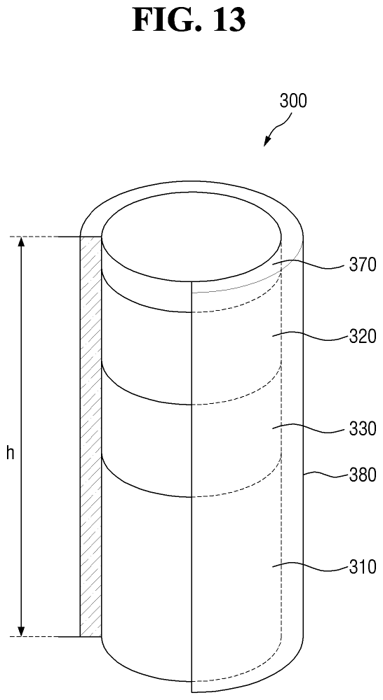

FIG. 13 is a schematic diagram illustrating the light-emitting element according to an embodiment.

The light-emitting element 300 may be a light-emitting diode (LED). Specifically, the light-emitting element 300 may be an inorganic LED having a micrometer unit or nanometer unit size and made of an inorganic material. The inorganic light-emitting diode may be aligned between two electrodes in which polarity is formed by forming an electric field in a specific direction between the two electrodes facing each other. The light-emitting element 300 may be aligned between two electrodes by an electric field formed on the two electrodes.

The light-emitting element 300 may include a semiconductor crystal doped with an arbitrary conductivity type (e.g., p-type or n-type) impurity. The semiconductor crystal may receive an electrical signal applied from an external power source and emit light in a specific wavelength range.

Referring to FIG. 13, the light-emitting element 300 according to an embodiment may include a first conductivity type semiconductor 310, a second conductivity type semiconductor 320, an active layer 330, and an insulating film 380. The light-emitting element 300 according to an embodiment may further include at least one conductive electrode layer 370. Although FIG. 13 illustrates that the light-emitting element 300 further includes a conductive electrode layer 370, the disclosure is not limited thereto. In some cases, the light-emitting element 300 may include a greater number of conductive electrode layers 370, or the conductive electrode layers 370 may be omitted. Descriptions of the light-emitting element 300, which will be made below, may be identically applied even in case that the number of conductive electrode layers 370 is varied or another structure is further included.

The light-emitting element 300 may have a shape extending in a direction. The light-emitting element 300 may have a shape of nanorods, nanowires, nanotubes, or the like. In an embodiment, the light-emitting element 300 may have a cylindrical shape or a rod shape. However, the shape of the light-emitting element 300 is not limited thereto and may have various shapes such as a regular hexahedral shape, a rectangular parallelepiped shape, a hexagonal columnar shape, and the like. Semiconductors included in the light-emitting element 300, which will be described below, may have a structure in which the semiconductors are sequentially disposed or stacked in the direction.

The light-emitting element 300 according to an embodiment may emit light in a specific wavelength range. In an example, the active layer 330 may emit blue light having a central wavelength range of about 450 nm to about 495 nm. However, the central wavelength range of the blue light is not limited to the above range, and it should be understood that the central wavelength range includes all wavelength ranges which can be recognized as a blue color in the art. Further, the light emitted from the active layer 330 of the light-emitting element 300 is not limited thereto, and the light may be green light having a central wavelength range of about 495 nm to about 570 nm or red light having a central wavelength range of about 620 nm to about 750 nm.

To describe the light-emitting element 300 in detail with reference to FIG. 13, the first conductivity type semiconductor 310 may be an n-type semiconductor having, for example, a first conductivity type. For example, in case that the light-emitting element 300 emits light in a blue wavelength range, the first conductivity type semiconductor 310 may include a semiconductor material having a chemical formula of InₓAl_{y}Ga_{1-x-y}N (0≤x≤1, 0≤y≤1, and 0≤x+y≤1). For example, the semiconductor material may be one or more among InAlGaN, GaN, AlGaN, InGaN, AlN, and InN which are doped with an n-type impurity. The first conductivity type semiconductor 310 may be doped with a first conductive dopant. For example, the first conductivity type dopant may be Si, Ge, Sn, or the like. In an example, the first conductivity type semiconductor 310 may be n-GaN doped with n-type Si. A length of the first conductivity type semiconductor 310 may range from about 1.5 μm to about 5 μm, but the disclosure is not limited thereto.

The second conductivity type semiconductor 320 is disposed on the active layer 330 which will be described below. For example, the second conductivity type semiconductor 320 may be a p-type semiconductor having a second conductivity type. For example, in case that the light-emitting element 300 emits light in a blue or green wavelength range, the second conductivity type semiconductor 320 may include a semiconductor material having a chemical formula of InₓAl_{y}Ga_{1-x-y}N (0≤x≤1, 0≤y≤1, and 0≤x+y≤1). For example, the semiconductor material may be one or more among InAlGaN, GaN, AlGaN, InGaN, AlN, and InN which are doped with a p-type impurity. The second conductivity type semiconductor 320 may be doped with a second conductive dopant. For example, the second conductive dopant may be Mg, Zn, Ca, Se, Ba, or the like. In an example, the second conductivity type semiconductor 320 may be p-GaN doped with p-type Mg. A length of the second conductivity type semiconductor 320 may range from about 0.08 μm to about 0.25 μm, but the disclosure is not limited thereto.

FIG. 13 illustrates that each of the first conductivity type semiconductor 310 and the second conductivity type semiconductor 320 is formed as a layer, but the disclosure is not limited thereto. In some cases, each of the first conductivity type semiconductor 310 and the second conductivity type semiconductor 320 may further include a greater number of layers, for example, a clad layer or a tensile strain barrier reducing (TSBR) layer according to a material of the active layer 330.

The active layer 330 is disposed between the first conductivity type semiconductor 310 and the second conductivity type semiconductor 320. The active layer 330 may include a material having a single or multiple quantum well structure. In case that the active layer 330 includes a material having a multiple quantum well structure, the active layer 330 may have a structure in which quantum layers and well layers are alternately stacked. The active layer 330 may emit light by combination or coupling of electron-hole pairs in response to an electrical signal applied through the first conductivity type semiconductor 310 and the second conductivity type semiconductor 320. In an example, in case that the active layer 330 emits light in a blue wavelength range, the active layer 330 may include a material such as AlGaN, AlInGaN, or the like. In particular, in case that the active layer 330 has a multiple quantum well structure in which quantum layers and well layers are alternately stacked, the quantum layer may include a material such as AlGaN or AlInGaN, and the well layer may include a material such as GaN or AlInN. In an example, the active layer 330 includes AlGaInN as the quantum layer and AlInN as the well layer. As described above, the active layer 330 may emit blue light having a central wavelength range of about 450 nm to about 495 nm.

However, the disclosure is not limited thereto, and the active layer 330 may have a structure in which a semiconductor material having large band gap energy and a semiconductor material having small band gap energy are alternately stacked or may include different Group III to V semiconductor materials according to a wavelength range of emitted light. The light emitted from the active layer 330 is not limited to light in a blue wavelength range, and in some cases, the active layer 330 may emit light in a red or green wavelength range. A length of the active layer 330 may range from about 0.05 μm to about 0.25 μm, but the disclosure is not limited thereto.

The light emitted from the active layer 330 may be emitted to an outer surface of the light-emitting element 300 in a length direction and both side surfaces thereof. Directivity of the light emitted from the active layer 330 is not limited to a direction.

The conductive electrode layer 370 may be an ohmic contact electrode. However, the disclosure is not limited thereto, and the conductive electrode layer 370 may be a Schottky contact electrode. The conductive electrode layer 370 may include a conductive metal. For example, the conductive electrode layer 370 may include at least one among Al, Ti, In, Au, Ag, ITO, IZO, and ITZO. The conductive electrode layer 370 may include a semiconductor material doped with an n- or p-type impurity. The conductive electrode layer 370 may include a same material or different materials, but the disclosure is not limited thereto.

The insulating film 380 may surround the outer surfaces of the semiconductors which are described above. In an example, the insulating film 380 may surround at least the outer surface of the active layer 330 and may extend in a direction in which the light-emitting element 300 extends. The insulating film 380 may perform a function of protecting the members. As an example, the insulating film 380 may surround side surfaces of the members and expose two end portions of the light-emitting element 300 in the length direction.

FIG. 13 illustrates that the insulating film 380 extends in the length direction of the light-emitting element 300 to cover (or overlap) the first conductivity type semiconductor 310, the second conductivity type semiconductor 320, the active layer 330, and the conductive electrode layer 370, but the disclosure in not limited thereto. The insulating film 380 covers only the outer surfaces of some semiconductor layers including the active layer 330 or covers only a portion of the outer surface of the conductive electrode layer 370 so that another portion of the outer surface of the conductive electrode layer 370 may be exposed.

A thickness of the insulating film 380 may range from about 10 nm to about 1.0 μm, but the disclosure is not limited thereto. The thickness of the insulating film 380 may be about 40 nm.

The insulating film 380 may include materials having insulation properties, for example, SiOₓ, SiNₓ, SiOₓN_{y}, AlN, Al₂O₃, and the like. Thus, it is possible to prevent an electrical short circuit which may occur in case that the active layer 330 directly contacts an electrode through which an electrical signal is transmitted to the light-emitting element 300. Since the insulating film 380 protects the outer surface of the light-emitting element 300 including the active layer 330, it is possible to prevent degradation in light emission efficiency.

In some embodiments, the outer surface of the insulating film 380 may be surface-treated. In case that the display panel 10 is manufactured, the light-emitting element 300 may be sprayed onto an electrode in a state of being dispersed in an ink. Here, in order to allow the light-emitting element 300 to maintain the dispersed state without being agglomerated with adjacent another light-emitting element 300 in the ink, the insulating film 380 may be hydrophobically or hydrophilically surface-treated.

The light-emitting element 300 may have a length h ranging from about 1 μm to about 10 μm or from about 2 μm to about 5 μm, or equal to about 4 μm. A diameter of the light-emitting element 300 may range from about 300 nm to about 700 nm, and an aspect ratio of the light-emitting element 300 may range from about 1.2 to about 100. However, the disclosure is not limited thereto, and the light-emitting elements 300 included in the display panel 10 may have different diameters according to a difference in composition of the active layers 330. The diameter of the light-emitting element 300 may have a range of about 500 nm.

The display panel 10 may further include a light-emitting element 300 having a structure different from that of the light-emitting element 300 of FIG. 13.

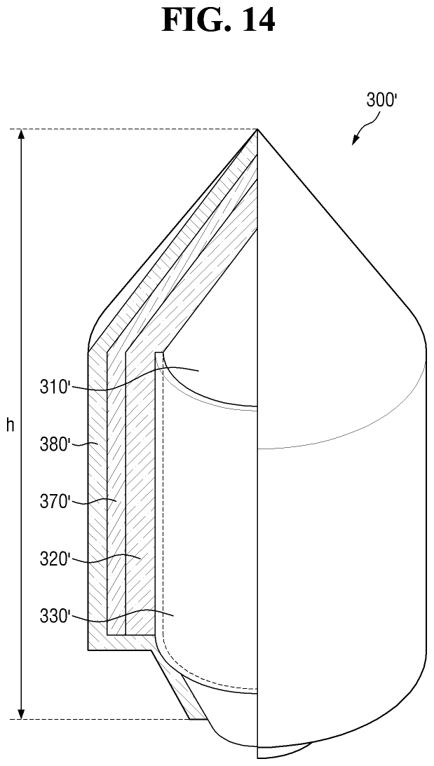

FIG. 14 is a schematic diagram illustrating a light-emitting element according to an embodiment.

Referring to FIG. 14, a light-emitting element 300′ may be formed such that layers are not stacked in a direction and each of the layers surrounds an outer surface of another layer. The light-emitting element 300′ of FIG. 14 is the same as the light-emitting element 300 of FIG. 13 except that shapes of the layers are partially different from each other. Hereinafter, the same descriptions will be omitted, and differences will be described.

According to an embodiment, a first conductivity type semiconductor 310′ may extend in a direction, and both end portions thereof may be formed to be inclined toward a central portion thereof. The first conductivity type semiconductor 310′ of FIG. 14 may have a shape in which a rod-shaped or cylindrical main body and conical-shaped end portions on upper and lower portions of the main body are formed. An upper end portion of the main body may have a slope that is steeper than a slope of a lower end portion thereof.

An active layer 330′ may surround an outer surface of the main body of the first conductivity type semiconductor 310′. The active layer 330′ may have an annular shape extending in a direction. The active layer 330′ may not be formed on upper and lower end portions of the first conductivity type semiconductor 310′. For example, the active layer 330′ may electrically contact only a parallel side surface of the first conductivity type semiconductor 310′.

A second conductivity type semiconductor 320′ may surround an outer surface of the active layer 330′ and the upper end of the first conductivity type semiconductor 310′. The second conductivity type semiconductor 320′ may include an annular-shaped main body extending in a direction and an upper end portion having an inclined side surface. For example, the second conductivity type semiconductor 320′ may directly contact a parallel side surface of the active layer 330′ and an inclined upper end portion of the first conductivity type semiconductor 310′. However, the second conductivity type semiconductor 320′ is not formed in the lower end of the first conductivity type semiconductor 310′.

An electrode material layer (or electrode layer) 370′ may surround an outer surface of the second conductivity type semiconductor 320′. For example, the electrode layer 370′ and the second conductivity type semiconductor 320′ may have substantially a same shape. For example, the electrode layer 370′ may entirely contact the outer surface of the second conductivity type semiconductor 320′.

An insulating film 380′ may surround the electrode layer 370′ and the outer surface of the first conductivity type semiconductor 310′. The insulating film 380′ may be in direct contact with, in addition to the electrode layer 370′, the lower end of the first conductivity type semiconductor 310′, and exposed lower ends of the active layer 330′ and the second conductivity type semiconductor 320′.

In concluding the detailed description, those skilled in the art will appreciate that many variations and modifications can be made to the embodiments without substantially departing from the principles of the disclosure. Therefore, the disclosed embodiments of the disclosure are used in a generic and descriptive sense only and not for purposes of limitation.

1. A display device comprising:
a light-emitting element;
a first transistor that transmits a driving current to the light-emitting element;
a second transistor that transmits a data signal to the first transistor, wherein
the first transistor includes a first active layer,
the second transistor includes a second active layer an oxide semiconductor, and
the light-emitting element includes:
a first conductivity type semiconductor having a first polarity;
a second conductivity type semiconductor having a second polarity different from the first polarity; and
an active layer disposed between the first conductivity type semiconductor and the second conductivity type semiconductor.

2. The display device of claim 1, wherein the first active layer of the first transistor includes an oxide semiconductor.

3. The display device of claim 2, wherein the oxide semiconductor of each of the first active layer and the second active layer includes indium-gallium-tin oxide (IGTO) or indium-gallium-zinc-tin oxide (IGZTO))

4. The display device of claim 3, wherein
a length of the light-emitting element is in a range of about 4 μm to about 7 μm, and
an aspect ratio of the light-emitting element is in a range of about 1.2 to about 100.

5. The display device of claim 2, wherein the first transistor includes a first gate electrode disposed below the first active layer.

6. The display device of claim 1, wherein the first active layer includes:
a first conductorized region;
a second conductorized region; and
a channel region disposed between the first conductorized region and the second conductorized region.

7. The display device of claim 6, wherein the first transistor further includes:
a third gate electrode disposed on the first active layer;
a first source electrode electrically connected to the first conductorized region through a first contact hole passing through an interlayer insulating film disposed on the third gate electrode; and
a first drain electrode electrically connected to the second conductorized region through a second contact hole passing through the interlayer insulating film.

8. The display device of claim 7, wherein the first active layer includes polycrystalline silicon.

9. The display device of claim 8, wherein the first transistor further includes a light blocking layer disposed below the first active layer.

10. The display device of claim 1, wherein the second transistor includes:
a second gate electrode disposed below the second active layer;
a second source electrode electrically connected to side of the second active layer; and
a second drain electrode electrically connected to another side of the second active layer.

11. The display device of claim 10, further comprising a data line that transmits the data signal,
wherein the data line further includes:
a conductive pattern spaced apart from the second source electrode of the second transistor and electrically connected to the data line and the second source electrode.

12. A display device comprising:
a first gate electrode disposed on substrate;
a first gate insulating film disposed on the first gate electrode;
a first active layer disposed on the first gate insulating film, at least partially overlapping the first gate electrode, and including an oxide semiconductor;
a first interlayer insulating film disposed on the first active layer;
a second gate electrode disposed on the first interlayer insulating film;
a second interlayer insulating film disposed on the second gate electrode;
a second active layer disposed on the second interlayer insulating film, at least partially overlapping the second gate electrode, and including an oxide semiconductor; and
a first conductive layer including:
a first signal line disposed on the second interlayer insulating film; and
a source electrode formed on one side of the second active layer,
wherein the first conductive layer further includes a conductive pattern at least partially overlapping side of the source electrode and the first signal line.

13. The display device of claim 12, further comprising:
a drain electrode disposed on the first gate insulating film and electrically contacting a side of the first active layer;
a via layer disposed on the first conductive layer; and
at least one light-emitting element disposed on the via layer, wherein the drain electrode is electrically connected to an end of the at least one light-emitting element.

14. The display device of claim 13, wherein the at least one light-emitting element includes:
a first conductivity type semiconductor having a first polarity;
a second conductivity type semiconductor having a second polarity different from the first polarity; and
an active layer disposed between the first conductivity type semiconductor and the second conductivity type semiconductor.

15. A display device comprising:
a base layer;
a first electrode and a second electrode disposed on the base layer and spaced apart from each other in a first direction;
at least one light-emitting element electrically connected to at least one of the first electrode and the second electrode and extending in the first direction;
a driving transistor that transmits a driving current to the at least one light-emitting element, wherein
the driving transistor includes an active layer having an oxide semiconductor, and
the at one light-emitting element includes;
a first conductivity type semiconductor having a first polarity;
a second conductivity type semiconductor having a second polarity different from the first polarity; and
an active disposed between the first conductivity type semiconductor and the second conductivity type semiconductor.

16. The display device of claim 15, wherein the driving transistor has a gate electrode disposed below the active layer.

17. The display device of claim 16, wherein each of the first electrode and the second electrode extends in a second direction different from the first direction.

18. The display device of claim 17, further comprising:
a first contact electrode contacting the first electrode and an end portion of the at least one light-emitting element; and
a second contact electrode electrically contacting-the second electrode and another end portion of the at least one light-emitting element.

19. The display device of claim 17, wherein
a length of the at least one light-emitting element in the first direction is in a range of about 4 μm to about 7 μm, and
an aspect ratio of the at least one light-emitting element is in a range of about 1.2 to about 100.

20. The display device of claim 19, wherein the first conductivity type semiconductor, the active layer, and the second conductivity type semiconductor are disposed in a direction parallel to an upper surface of the base layer.
